(19) United States
(12) Patent Application Publication
(10) Pub. No.: US 2010/0206720 A1
(43) Pub. Date: Aug. 19, 2010

(54) METHOD OF PRODUCING INORGANIC NANOPARTICLES

(75) Inventors: Kuan-Jiuh Lin, Taichung City (TW); Chuen-Yuan Hsu, Yunlin County (TW)

Correspondence Address: OSHA LIANG L.L.P., TWO HOUSTON CENTER, 909 FANNIN, SUITE 3500, HOUSTON, TX, 77010, US

(73) Assignee: Kuan-Jiuh Lin, Taichung City (TW)

(21) Appl. No.: 12/470,918

(22) Filed: May 22, 2009

(30) Foreign Application Priority Data
Feb. 17, 2009 (TW) 098104954

(51) Int. Cl. C23C 14/32; C23C 14/00

(52) U.S. Cl. 204/192.35; 204/192.32; 204/298.38

(57) ABSTRACT

A method of producing inorganic nanoparticles includes: (a) providing a layered structure including a substrate and an inorganic layer; (b) disposing the layered structure in a vacuum chamber, vacuuming the vacuum chamber, and introducing a gas into the vacuum chamber; and (c) applying microwave energy to the gas to produce a microwave plasma of the gas within the vacuum chamber so that the inorganic layer is acted by the microwave plasma and formed into a plurality of inorganic nanoparticles on the substrate. A system for producing the nanoparticles is also disclosed.

### CROSS-REFERENCE TO RELATED APPLICATION

This application claims priority of Taiwanese application No. 098104954, filed on Feb. 17, 2009.

### BACKGROUND OF THE INVENTION

1. Field of the Invention

This invention relates to a method of producing inorganic nanoparticles, more particularly to a method employing microwave energy to produce microwave plasma for acting on an inorganic layer, thereby forming a plurality of inorganic nanoparticles.

2. Description of the Related Art

Nano-material usually includes nanoparticles, nanofiber, nano-film, and nano-bulk. Among others, since nanoparticles have been developed for a longer period of time, technologies thereof are more mature than others. Further, as nanofiber and nano-film are made from nanoparticles, production of nanoparticles is relatively important. In general, methods of producing nanoparticles are classified into physical method and chemical method.

A major example of chemical method is chemical reduction. In the chemical reduction, nanoparticles are formed through reduction of metal ions in a solution, to which a protecting agent is added so as to maintain uniform distribution of the nanoparticles therein and prevent aggregation of the nanoparticles. After the nanoparticles are covered by the protecting agent, a substrate, which has a surface modified with an organic functional group, is provided for formation of a self-assembly nanostructure, such as nanoparticles, thereon through static attraction force and chemical bonding therebetween. Solutions containing organic materials, such as toluene and thiol-containing organic molecules, are usually used in the chemical reduction. However, the organic materials are likely to contaminate the environment and are harmful to human health.

Examples of physical methods for producing nanoparticles include high temperature annealing, electron beam irradiation, heavy ion irradiation, pulsed laser irradiation, and nanolithography. In the first four of the physical methods, a thin film is heated so as to form cracks, become discontinuous, and be melted. Thereafter, spherical nanoparticles are formed by surface tension forces. In the last one of the physical methods, a substrate is covered by a specific mask. For example, nano-scale silicon particles are arranged in a hexagonal closed-packed structure. Subsequently, a metal is deposited on interstices of the hexagonal closed-packed structure such that the nanoparticles are formed and arranged in a triangular array. However, the above-mentioned five physical methods have the following disadvantages.

In the high temperature annealing method, raising and lowering temperature require a long period of time, which results in time-consumption and low efficiency, and non-uniform morphology and easy aggregation of the nanoparticles.

In the electron beam irradiation method, expensive equipment, such as an electron gun, is needed. In addition, since an electron beam generated from the electron gun can merely focus on a limited region on the substrate in each operation, a long time is required for producing nanoparticles on the substrate having a large area. Thus, the method is also less effective.

In the heavy ion irradiation method, the disadvantages are similar to those in the electron beam irradiation method, and the application thereof is still limited to academic study.

The pulsed laser irradiation method is also less effective because a laser source can irradiate only a small region of the substrate and needs to move forth and back to treat a large area of the substrate.

In the nanolithography method, although mass production of nanoparticles is possible, the method is complicated and time-consuming, and requires organic solvents to clean the substrate, which is not environmentally friendly.

### SUMMARY OF THE INVENTION

Therefore, an object of the present invention is to provide a method of producing inorganic nanoparticles that can overcome the aforesaid drawbacks associated with the prior art.

Another object of this invention is to provide a system for producing inorganic nanoparticles on a substrate.

According to one aspect of the present invention, a method of producing inorganic nanoparticles comprises: (a) providing a layered structure including a substrate and an inorganic layer that is formed on the substrate and that is made from a material selected from the group consisting of a metal, a metal oxide, a metal alloy, and combinations thereof; (b) disposing the layered structure in a vacuum chamber, vacuuming the vacuum chamber, and introducing a gas into the vacuum chamber; and (c) applying microwave energy to the gas to produce a microwave plasma of the gas within the vacuum chamber so that the inorganic layer is acted by the microwave plasma and formed into a plurality of spaced apart inorganic nanoparticles on the substrate.

According to another aspect of the present invention, a system for producing a plurality of spaced apart inorganic nanoparticles comprises: a reactor having a chamber, and gas outlet and inlet in fluid communication with the chamber; a vacuum unit connected to the gas outlet to vacuum the chamber; a gas supply unit connected to the gas inlet and introducing a gas into the chamber through the gas inlet; a microwave-generating unit for supplying microwave energy to the gas, thereby producing a microwave plasma of the gas therein; and a layered structure disposed inside the chamber and including a substrate and an inorganic layer on the substrate.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a perspective view of a preferred embodiment of a system for producing inorganic nanoparticles according to this invention;

FIG. 2 is a flowchart to illustrate consecutive steps of a preferred embodiment of the method of producing inorganic nanoparticles according to this invention.

FIG. 3a is a fragmentary schematic view to illustrate an inorganic layer formed on a substrate before a microwave plasma treatment;

FIG. 3b is a fragmentary schematic view to illustrate a plurality of inorganic nanoparticles formed on the substrate after the microwave plasma treatment;

FIG. 4 is a scanning electron microscopic view showing the results of Example 1;

FIG. 5 is a plot of thickness of the inorganic layer versus particle diameter of nanoparticles for Example 1;

FIG. 6 is a scanning electron microscopic view showing the results of Example 2;

FIG. 7 is a plot of thickness of the inorganic layer versus particle diameter of nanoparticles for Example 2;

FIG. 8 is a scanning electron microscopic view for Example 3;

FIG. 9 is a plot of thickness of the inorganic layer versus particle diameter of nanoparticles for Example 3;

FIG. 10 is a scanning electron microscopic view for Example 5;

FIG. 11 is a UV absorption spectrum for Example 5;

FIG. 12 is a scanning electron microscopic view for Example 6; and

FIG. 13 is an X-ray photoelectron spectroscopy spectrum for Example 6.

### DETAILED DESCRIPTION OF THE PREFERRED EMBODIMENT

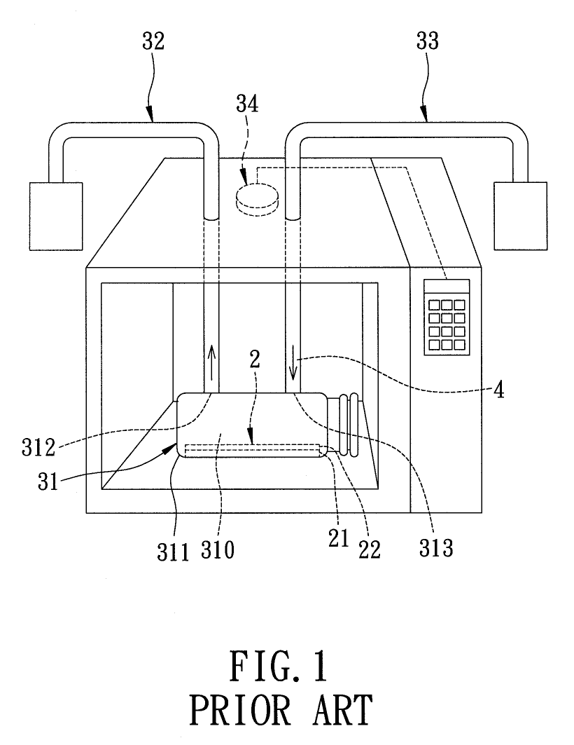

Referring to FIG. 1, there is shown a system for producing inorganic nanoparticles according to a preferred embodiment of this invention. The system includes a reactor 31, a vacuum unit 32 connected to the reactor 31, a gas supply unit 33, a microwave-generating unit 34, and a layered structure 2.

The reactor 31 includes a surrounding wall 311 defining a chamber 310 therein, and has gas outlet and inlet 312, 313 in fluid communication with the chamber 310.

The vacuum unit 32 is connected to the gas outlet 312 of the reactor 31 so as to vacuum the chamber 310.

The gas supply unit 33 is connected to the gas inlet 313 of the reactor 31 so as to introduce a gas 4 into the chamber 310 through the gas inlet 313. The gas 4 may be selected from the group consisting of argon, nitrogen, oxygen, and combinations thereof according to the type of nanoparticles to be produced. When the inorganic nanoparticles are made from a metal, an inert gas, such as argon or nitrogen, is supplied to the chamber 310. On the other hand, when the inorganic nanoparticles are made from a metal oxide, oxygen is supplied to the chamber 310.

The microwave-generating unit 34 is provided to face the chamber 310 and to supply microwave energy to the gas 4 so that a microwave plasma of the gas 4 is produced within the chamber 310. Preferably, the microwave-generating unit 34 has an output power ranging from 700 W to 1500 W. In this embodiment, the output power is substantially 1100 W and the frequency is set to be 2450 MHz.

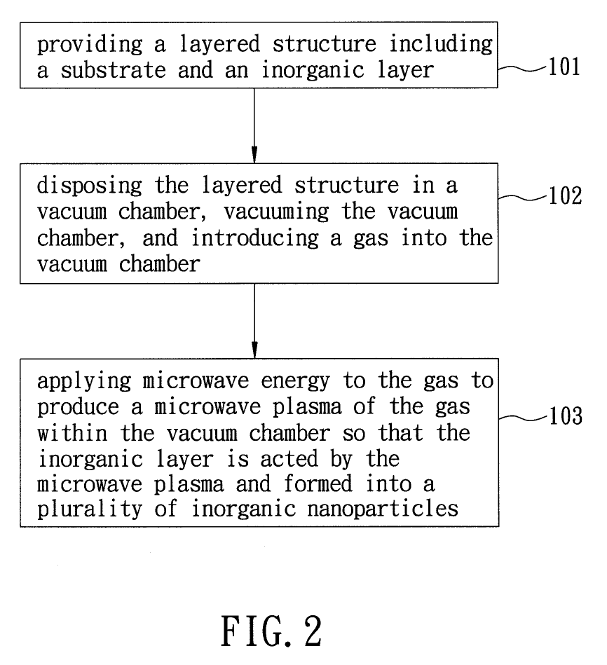

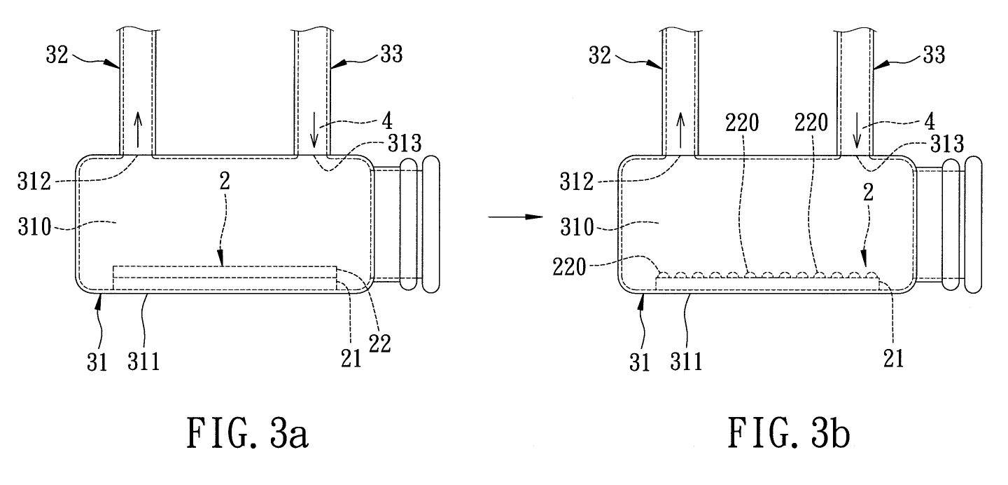

Referring to FIGS. 1, 2, 3a and 3b, a method of producing the inorganic nanoparticles 220 of a preferred embodiment, which is embodied in the system of FIG. 1, includes steps 101 to 103.

In step 101, a layered structure 2 is provided. The layered structure 2 includes a substrate 21 and an inorganic layer 22 that is formed on the substrate 21 and that has a predetermined thickness. The inorganic layer 22 is made from a material selected from the group consisting of a metal, a metal oxide, a metal alloy, and combinations thereof.

Preferably, the metal is selected from the group consisting of gold (Au), silver (Ag), palladium (Pd), platinum (Pt), chromium (Cr), cobalt (Co), molybdenum (Mo), copper (Cu), nickel (Ni), aluminum (Al), iron (Fe), magnesium (Mg), tin (Sn), titanium (Ti), thallium (Ta), iridium (Ir), and combinations thereof.

Preferably, the metal oxide includes a metal selected from the group consisting of chromium, cobalt, molybdenum, copper, nickel, aluminum, iron, magnesium, tin, titanium, thallium, iridium, and combinations thereof.

Preferably, the metal alloy includes at least two metals selected from the group consisting of gold, silver, palladium, platinum, chromium, cobalt, molybdenum, copper, nickel, aluminum, iron, magnesium, tin, titanium, thallium, iridium, and combinations thereof.

The material for the substrate 21 is not limited. Preferably, the substrate 21 can be selected from the group consisting of silicon wafer, glass substrate, quartz substrate, sapphire and mica. Method of forming the inorganic layer 22 on the substrate 21 is also not limited. In this embodiment, the inorganic layer 22 is formed on the substrate 21 using sputter coating and has a predetermined thickness controlled using a film thickness measuring instrument (F.T.M).

It is worth mentioning that the inorganic layer 22 can be also made of a metal alloy oxide, such as indium tin oxide (ITO). Likewise, the indium tin oxide layer is formed on the substrate 21 using sputter coating.

Preferably, the inorganic layer 22 has a layer thickness ranging from 1 nm to 20 nm. By means of control of the thickness of the inorganic layer 22, a diameter of the produced inorganic nanoparticles 220 can be controlled.

In step 102, the layered structure 2 is disposed in the chamber 310 of the reactor 31, and the chamber 310 is vacuumed through the vacuum unit 32. Subsequently, the gas 4 is introduced into the chamber 310 through the gas supply unit 33. In this embodiment, the chamber 310 has a pressure ranging from 0.2 torr to 6.0 torr.

In step 103, microwave energy is supplied to the chamber 103 for a predetermined time so that the gas 4 in the chamber 103 is formed into a microwave plasma which acts on the inorganic layer 22, thereby melting the inorganic layer 22 and forming a plurality of spaced apart inorganic nanoparticles 220 on the substrate 21. In this embodiment, by means of control of the thickness of the inorganic layer 22, the particle size of the inorganic nanoparticles 220 can be controlled to range from 3 nm to 200 nm. In practical use, the particle diameter of the inorganic nanoparticles should not be limited. In addition, a duration time of the microwave energy may be varied depending on the layer thickness and an area of the inorganic layer 22. When the layer thickness and the area of the inorganic layer 22 are large, more energy is required for melting the inorganic layer 22, thereby increasing the duration time of supply of the microwave energy.

It is worth mentioning that if a metal alloy is to be used for making the inorganic nanoparticles 220, the metal alloy may include at least two metals selected from the group consisting of gold, silver, palladium, platinum, chromium, cobalt, molybdenum, copper, nickel, aluminum, iron, magnesium, tin, titanium, thallium, and iridium. The metal alloy should be formed as an inorganic layer on the substrate 21. Alternatively, a plurality of inorganic layers 22 having different pure metals can be formed on the substrate 21. In this case, each of the inorganic layers may be made of a metal selected from the group consisting of gold, silver, palladium, platinum, chromium, cobalt, molybdenum, copper, nickel, aluminum, iron, magnesium, tin, titanium, thallium, and iridium. For example, when gold-silver alloy nanoparticles are to be produced, a first layer made of gold is formed on the substrate 21 and a second layer made of silver is formed on the first layer. Subsequently, the metals of the first and second layers are melted and mixed together by the action of the microwave plasma, and are then formed into nanoparticles spontaneously through surface tension forces. Preferably, the inorganic layers 22 have a total thickness ranging from 1 nm to 20 nm. Each of the inorganic layers 22 has a thickness ranging from 0.1 nm to 19.9 nm.

Alternatively, when the inorganic layers 22 are formed on the substrate 21,the inorganic layers 22 may be made of the same material or different materials selected from the metals, the metal oxides, or the metal alloys which are described hereinbefore.

It is worth mentioning that, when the inorganic nanoparticles 220 made of a metal oxide are produced, the inorganic layer 22 formed on the substrate 21 is made of the metal oxide, and then is subjected to microwave plasma treatment, thereby forming the inorganic nanoparticles 220. Alternatively, the inorganic nanoparticles 220 made of the metal oxide can be produced by forming the inorganic layer 22 made of a metal on the substrate 21, and followed by introducing an oxygen gas into the chamber 310 such that the inorganic layer 22 is melted and oxidized by reacting with the microwave plasma of oxygen, thereby forming the inorganic nanoparticles 220.

The merits of the method of producing the inorganic nanoparticles 220 according to this invention will become apparent with reference to the following Examples.

### EXAMPLES 1-6

### EXAMPLE 1

### Production of Gold Nanoparticles

Eight substrate specimens having a size of 1 cm×1 cm were provided. The specimens were cleaned with acetone, ethanol, and deionized water, and further cleaned using an ultrasonic cleaner for 5 min so as to remove contaminations on the specimens. After a drying treatment through nitrogen gas, the specimens were dipped in a piranha solution containing H₂SO₄ and H₂O₂ in a ratio of 3:1 at 80° C. so as to remove organic residue thereon. Subsequently, the specimens were rinsed with deionized water, and then dried with nitrogen gas.

The eight specimens processed through the aforesaid cleaning steps were placed inside a sputter coater for deposit of an inorganic layer thereon. A film thickness measurement instrument (F.T.M) was used to control the thicknesses of the inorganic layers deposited on the specimens to be 1 nm, 2 nm, 3 nm, 4 nm, 5 nm, 6 nm, 7 nm, and 8 nm, respectively. Since the gold target was used, gold layers with different thicknesses were respectively formed on the eight specimens.

Each specimen having the inorganic layer formed thereon was put in the system of the invention including the microwave-generating unit 34. The chamber 310 was vacuumed to a pressure of 0.3 torr using the vacuum unit 32, argon gas was introduced into the chamber 310 through the gas supply unit 33, and the microwave-generating unit 34 was operated to supply microwave energy to the argon gas so as to produce a microwave plasma of the argon. When the microwave plasma was applied to the inorganic layer, the inorganic layer was gradually melted to form a plurality of spaced apart inorganic nanoparticles. The duration time of the microwave energy was varied with the thickness of the inorganic layer. The duration times of the microwave energy for the inorganic layers with thicknesses of 1 nm, 2 nm, 3 nm, 4 nm, 5 nm, 6 nm, 7 nm, and 8 nm were 30 s, 45 s, 50 s, 55 s, 60 s, 65 s, 70 s, and 75 s, respectively.

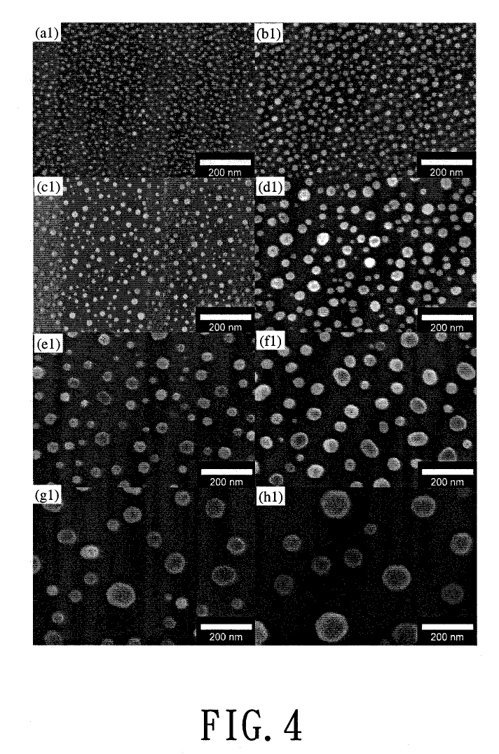

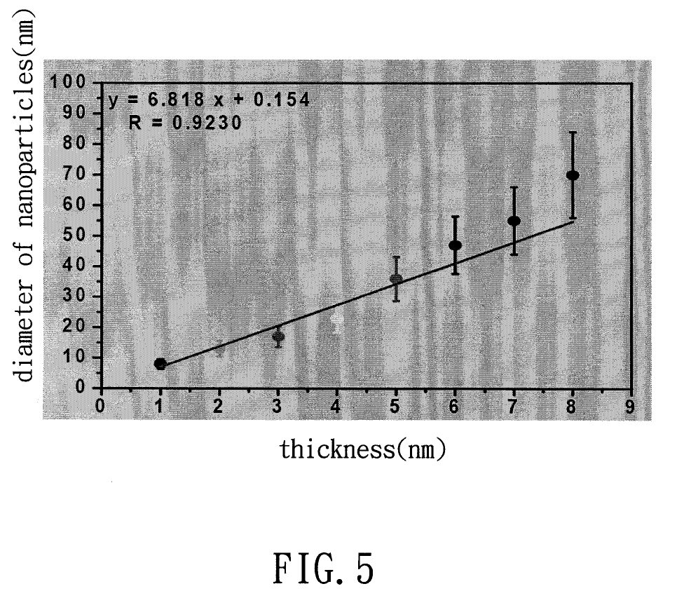

The specimens treated by the microwave plasma were analyzed using scanning electron microscope (SEM) and the SEM images of the specimens are labeled as a1, b1, c1, d1, e1, f1, g1, and h1, respectively in the order of from small thickness to large thickness of the inorganic layers on the specimens. The results are shown in FIG. 4 and indicate that when the thickness of the inorganic layer increases, the particle diameter of the produced inorganic nanoparticles is also increased. The results shown in the SEM images were thereafter processed to obtain average particle diameters. In particular, the particle diameters of some of the selected inorganic nanoparticles in each SEM image were measured, and an average diameter for the nanoparticles in each SEM image was calculated from the measured particle diameters. The results are shown in FIG. 5 which manifest a linear relation between the particle diameter of the inorganic nanoparticles and the thickness of the inorganic layer. Therefore, control of the particle diameter of the inorganic nanoparticles can be achieved by controlling the thickness of the inorganic layer.

### EXAMPLE 2

### Production of Silver Nanoparticles

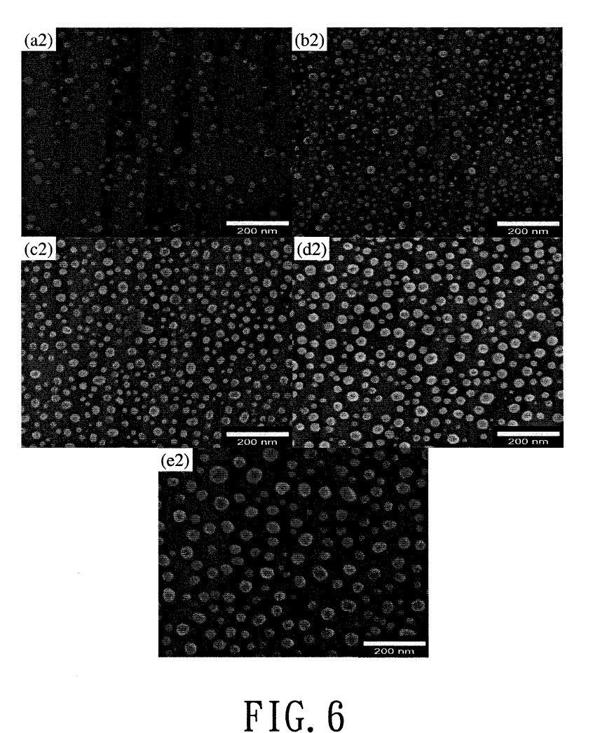

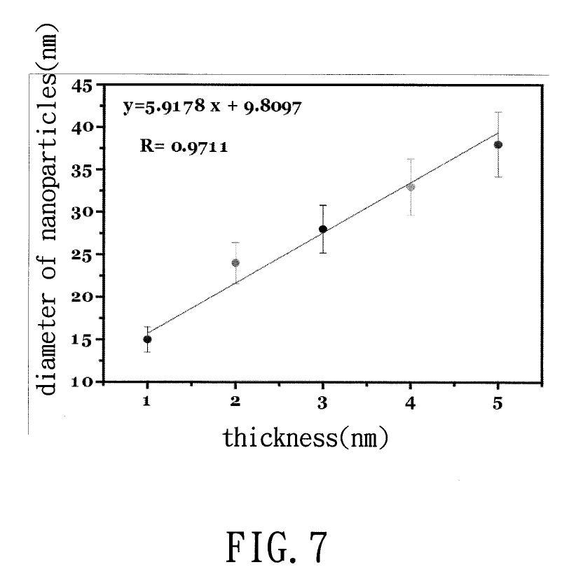

Example 2 was carried out following the procedure of Example 1. However, five substrate specimens were respectively formed with the inorganic layers with thicknesses of 1 nm, 2 nm, 3 nm, 4 nm, and 5 nm, and the duration times of the microwave energy for the inorganic layers were respectively 3 s, 6 s, 9 s, 12 s, and 15 s according to the different thicknesses of the inorganic layers. In addition, a silver target was used to form a silver layer on each substrate specimen. The specimens treated by the microwave plasma were analyzed using scanning electron microscope (SEM), and the resulting SEM images were labeled as a2, b2, c2, d2, and e2, respectively in the order of from small to large thickness of the inorganic layers. The results shown in FIGS. 6 and 7 indicate that when the thickness of the inorganic layer is increased, the particle diameter of the produced inorganic nanoparticles is also increased, and that the particle diameter of the inorganic nanoparticles and the thickness of the inorganic layer have a linear relationship. When the inorganic layer was made of silver, the duration time of the microwave energy for the inorganic layer is reduced compared to that for the inorganic layer made of gold. This is because the evaporation temperature of silver is low and the atom sputtering yield thereof is high. If the duration time is long, silver particles on the substrate will evaporate and disappear.

### EXAMPLE 3

### Production of Copper Oxide Nanoparticles

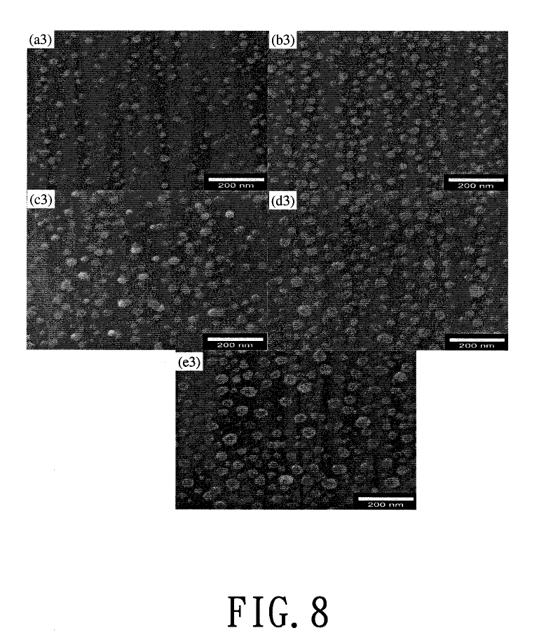

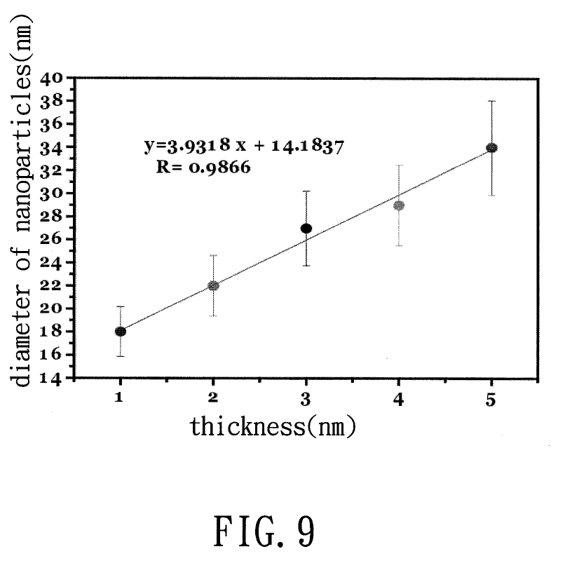

Example 3 was carried out following the procedure of Example 1. However, five substrate specimens were respectively formed with the inorganic layers with thicknesses of 1 nm, 2 nm, 3 nm, 4 nm, and 5 nm and the duration times of the microwave energy for the inorganic layers were respectively 15 s, 18 s, 21 s, 24 s, and 27 s. The inorganic layer was made of copper, the chamber was vacuumed to a pressure of 0.1 torr, and an oxygen gas was introduced into the chamber. After the microwave plasma treatment, the produced inorganic nanoparticles on the substrate specimens were analyzed by scanning electron microscope and the SEM images of the produced inorganic nanoparticles were labeled as a3, b3, c3, d3, and e3, respectively. The results shown in FIGS. 8 and 9 indicate that when the thickness of the inorganic layer is increased, the particle diameter of the produced inorganic nanoparticles is also increased, and that the diameter of the inorganic nanoparticles and the thickness of the inorganic layer have a linear relationship.

### EXAMPLE 4

### Production of Nickel Oxide Nanoparticles

Example 4 was carried out following the procedure of Example 3. However, the inorganic layer was made of nickel. The results of this example also show that when the thickness of the inorganic layer is increased, the particle diameter of the produced inorganic nanoparticles is also increased, and that the diameter of the inorganic nanoparticles and the thickness of the inorganic layer have a linear relationship.

### EXAMPLE 5

### Production of Gold-Silver Alloy Nanoparticles

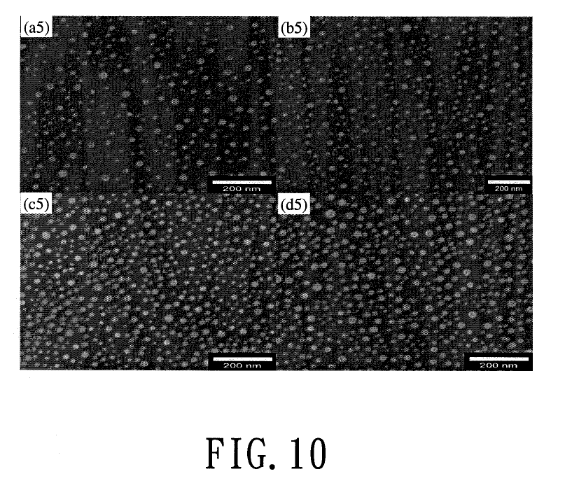

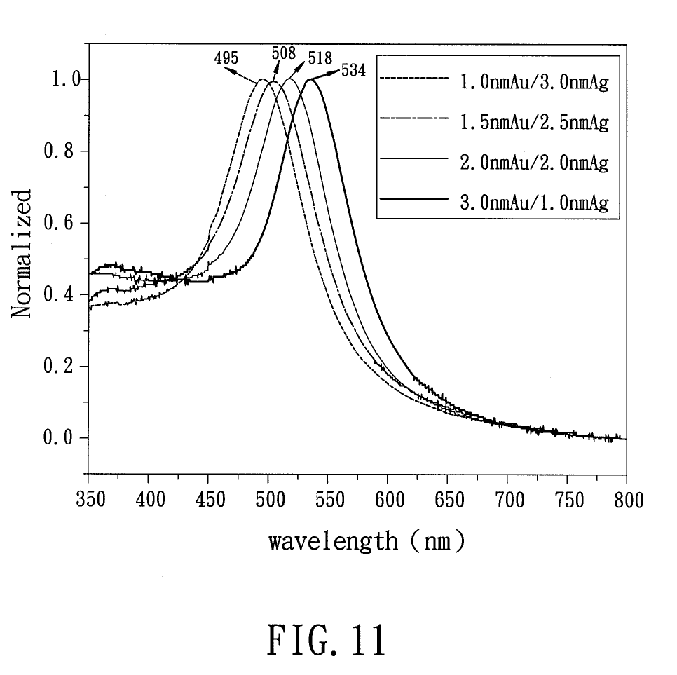

Example 5 was carried out following the procedure of Example 1. However, two metal layers were formed on the substrate. A first layer was deposited on the substrate by sputtering a gold target and then a second layer was formed on the first layer by sputtering a silver target. The resolution of the film thickness measurement was 0.1 nm. The film thickness that can be controlled ranged from 0.1 nm to 999 nm such that the minimal thickness of each layer can be controlled at 0.1 nm. The film thickness measurement instrument was used to control ratio of the thicknesses of the two metal layers and to maintain a total thickness of 4 nm for the two metal layers. Four substrate specimens were used in this example, and each specimen was formed with the two metal layers having the total thickness of 4 nm. The thickness ratios of the gold layer to the silver layer for the four specimens were respectively 1 nm:3 nm, 1.5 nm:2.5 nm, 2 nm:2 nm, and 3 nm:1 nm. The duration time of the microwave energy for each specimen was set to 20 s. After the microwave plasma treatment, the gold-silver alloy nanoparticles thus formed were analyzed by scanning electron microscope and the SEM images were labeled as a5, b5, c5, d5, and e5, respectively as shown in FIG. 10. FIG. 10 reveals that, although the metal layers are different in thickness for each specimen, as all of the specimens have the same total thickness, the particle diameters of the produced gold-silver alloy nanoparticles are substantially the same for all specimens. The average diameter of the nanoparticles obtained from statistical analysis of the SEM images is 21 nm±5 nm. FIG. 11 shows ultraviolet/visible (UV/vis) absorption spectra which indicate that, when the thickness ratios of the gold layer to the silver layer are different, the spectrum characteristics are different. FIG. 11 also shows that, when the amount of gold increases, the absorption peak shifts toward a spectrum range of 550-580 nm where the absorption peak of gold appears. The shift of the absorption peak proves that the nanoparticles as formed are alloys of gold and silver.

### EXAMPLE 6

### Production of Gold-Silver-Nickel-Palladium Alloy Nanoparticles

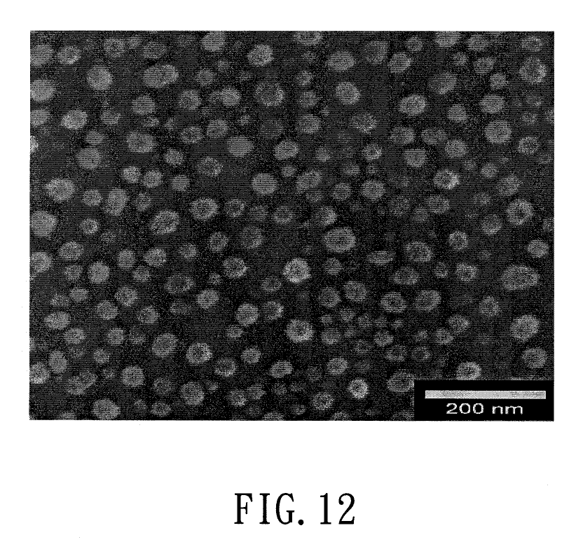

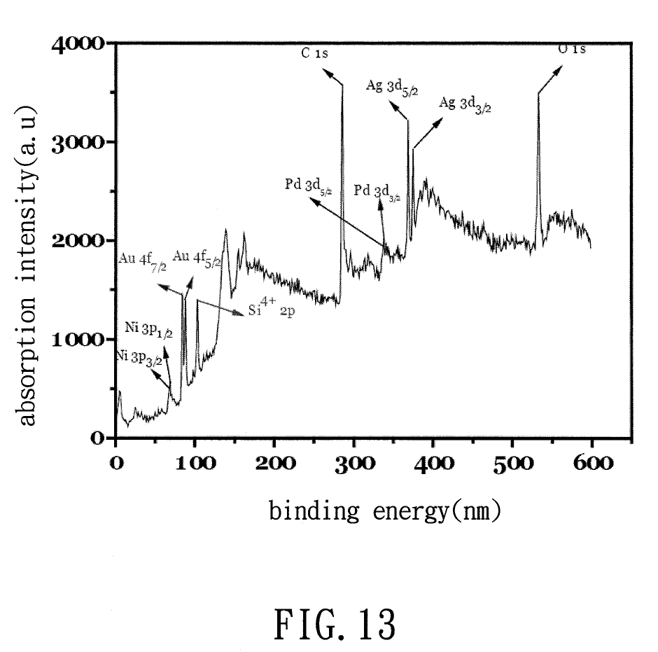

Example 6 was carried out following the procedure of Example 1. However, four metal layers made of gold, silver, nickel, and palladium were formed on a substrate specimen and the thicknesses thereof were 1 nm, 1 nm, 1.5 nm, and 1.5 nm, respectively. The total thickness of the four metal layers was 5 nm. After the microwave plasma treatment, the gold-silver-nickel-palladium alloy nanoparticles thus formed were analyzed by scanning electron microscope. The resulting SEM image is shown in FIG. 12. An average particle diameter obtained from statistical analysis of the SEM image is 38 nm±10 nm. Referring to FIG. 13, an X-ray photoelectron spectroscopy spectrum shows that binding energy peaks of gold, silver, nickel, and palladium are present, which indicates that the nanoparticles include an alloy of gold, silver, nickel, and palladium. Therefore, by controlling the number, the material and the thickness of the inorganic layers, various alloy nanoparticles having different composition ratios can be produced.

In conclusion, Examples 1 to 4 demonstrate that the particle size or diameter of the nanoparticles produced using the microwave plasma according to the present invention has a good linear relationship with the thickness of the inorganic layer formed on the substrate. Therefore, the particle size of the nanoparticles can be controlled precisely by controlling the thickness of the inorganic layer formed on the substrate.

In addition, from the nanoparticles produced in Examples 1-6, it was found that the nanoparticles were firmly bonded to the substrate and were not easily removed from the substrate. Even when no protecting layer is provided on the nanoparticles, the nanoparticles are not prone to separate from the substrate upon touching the surface of the substrate or applying an electrostatic force. For example, when the inorganic layer is made of gold, the gold nanoparticle is tightly bonded to the substrate. The bonding strength between the nanoparticles and the substrate increases when the duration time of supply of the microwave energy increases. The reason therefor may be possibly that portions of the nanoparticles are embedded in the substrate by the action of the high temperature microwave plasma.

In addition, the invention is advantageous in that the inorganic nanoparticles can be produced in a short time due to the use of the high temperature microwave plasma. Moreover, aside from pure metal nanoparticles, metal alloy nanoparticles can be produced by the present invention.

With the invention thus explained, it is apparent that various modifications and variations can be made without departing from the spirit of the present invention. It is therefore intended that the invention be limited only as recited in the appended claims.

What is claimed is:

1. A method of producing inorganic nanoparticles, comprising:
(a) providing a layered structure including a substrate and an inorganic layer that is formed on the substrate and that is made from a material selected from the group consisting of a metal, a metal oxide, a metal alloy, and combinations thereof;
(b) disposing the layered structure in a vacuum chamber, vacuuming the vacuum chamber, and introducing a gas into the vacuum chamber; and
(c) applying microwave energy to the gas to produce a microwave plasma of the gas within the vacuum chamber so that the inorganic layer is acted by the microwave plasma and formed into a plurality of spaced apart inorganic nanoparticles on the substrate.

2. The method of claim 1, wherein the inorganic layer has a layer thickness ranging from 1 nm to 20 nm.

3. The method of claim 1, wherein the vacuum chamber has a pressure ranging from 0.2 torr to 6.0 torr after introducing the gas.

4. The method of claim 1, wherein the inorganic nanoparticles have a diameter ranging from 3 nm to 200 nm.

5. The method of claim 1, wherein the gas is selected from the group consisting of argon, nitrogen, oxygen, and combinations thereof.

6. The method of claim 1, wherein the metal is selected from the group consisting of gold, silver, palladium, platinum, chromium, cobalt, molybdenum, copper, nickel, aluminum, iron, magnesium, tin, titanium, thallium, iridium, and combinations thereof.

7. The method of claim 1, wherein the metal oxide includes a metal selected from the group consisting of chromium, cobalt, molybdenum, copper, nickel, aluminum, iron, magnesium, tin, titanium, thallium, iridium, and combinations thereof.

8. The method of claim 1, wherein the metal oxide is a metal alloy oxide.

9. The method of claim 8, wherein the metal alloy oxide is indium tin oxide.

10. The method of claim 1, wherein the metal alloy includes at least two metals selected from the group consisting of gold, silver, palladium, platinum, chromium, cobalt, molybdenum, copper, nickel, aluminum, iron, magnesium, tin, titanium, thallium, and iridium.

11. The method of claim 1, which comprises a plurality of the inorganic layers.

12. The method of claim 11, wherein the inorganic layers have a total thickness ranging from 1 nm to 20 nm.

13. The method of claim 11, wherein the material in one of the inorganic layers is different from the material in the other one of the inorganic layers.

14. The method of claim 11, wherein the material in one of the inorganic layers is gold, and the material in the other one of the inorganic layers is silver.

15. A system for producing a plurality of spaced apart inorganic nanoparticles, said system comprising:
a reactor having a chamber, and gas outlet and inlet in fluid communication with said chamber;
a vacuum unit connected to said gas outlet to vacuum said chamber;
a gas supply unit connected to said gas inlet and introducing a gas into said chamber through said gas inlet;
a microwave-generating unit for supplying microwave energy to said gas, thereby producing a microwave plasma in said chamber; and
a layered structure disposed inside said chamber and including a substrate and an inorganic layer formed on said substrate, wherein said inorganic layer is acted by said microwave plasma and formed into the inorganic nanoparticles.

16. The system of claim 15, wherein the chamber has a pressure ranging from 0.2 torr to 6.0 torr.

17. The system of claim 15, wherein said gas is selected from argon, nitrogen, oxygen, and combinations thereof.

18. The system of claim 15, wherein the microwave-generating unit has an output power ranging from 700 W to 1500 W.

19. The system of claim 18, wherein the microwave-generating unit has an output power of 1100 W.

20. The system of claim 18, wherein the microwave-generating unit generates a microwave frequency of 2450 MHz.
